(19) United States
(12) Patent Application Publication
(10) Pub. No.: US 2025/0268028 A1
(43) Pub. Date: Aug. 21, 2025

(54) DISPLAY DEVICE AND MANUFACTURING METHOD THEREOF

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 19/051,190

(22) Filed: Feb. 12, 2025

(30) Foreign Application Priority Data
Feb. 15, 2024 (JP) 2024-021257

(51) Int. Cl. H10K 59/122; H10K 59/12

(52) U.S. Cl. CPC H10K 59/122; H10K 59/1201

(57) ABSTRACT

According to one embodiment, a display device includes a first lower electrode, a partition, a first organic layer, a first upper electrode, and a first cap layer. The partition surrounds the first organic layer, the first upper electrode and the first cap layer. The first organic layer has a first end portion and a second end portion located on a side opposite to the first end portion. A thickness of the first upper electrode immediately above the second end portion is greater than a thickness of the first upper electrode immediately above the first end portion. A thickness of the first cap layer immediately above the second end portion is greater than a thickness of the first cap layer immediately above the first end portion.

### CROSS-REFERENCE TO RELATED APPLICATION

This application is based upon and claims the benefit of priority from Japanese Patent Application No. 2024-021257, filed Feb. 15, 2024, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is the schematic cross-sectional view of the display device DSP along the A-B line of FIG. 2.

FIG. 4 is the schematic cross-sectional view of the major portion of the display device DSP along the C-D line of FIG. 2.

FIG. 5 is the schematic cross-sectional view of the major portion of the display device DSP along the E-F line of FIG. 2.

FIG. 6 is a diagram for explaining an evaporation device EV.

FIG. 7 is a diagram for explaining the vapor deposition of each upper electrode and each cap layer.

FIG. 8 is a diagram for explaining an example of the evaporation direction D when an upper electrode and a cap layer are formed in each subpixel.

FIG. 9 is a diagram for explaining another example of the evaporation direction D when an upper electrode and a cap layer are formed in each subpixel.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a cross-sectional view of subpixels SP2 and SP3 in which a stacked film FL1 is formed.

FIG. 17 is a cross-sectional view of subpixels SP2 and SP3 from which the stacked film FL1 has been removed.

### DETAILED DESCRIPTION

Embodiments described herein aim to provide a display device and a manufacturing method thereof such that the reduction in reliability can be prevented.

In general, according to one embodiment, a display device comprises a substrate, a first lower electrode provided above the substrate, an inorganic insulating layer which covers a peripheral portion of the first lower electrode, a partition which has a conductive lower portion provided on the inorganic insulating layer, and an upper portion provided on the lower portion, a first organic layer which is provided on the first lower electrode and includes a first light emitting layer, a first upper electrode which is provided on the first organic layer and is in contact with the lower portion of the partition, and a first cap layer provided on the first upper electrode. The partition surrounds the first organic layer, the first upper electrode and the first cap layer. The lower portion has a bottom layer provided on the inorganic insulating layer, and a stem layer provided between the bottom layer and the upper portion. The bottom layer and the upper portion protrude from a side surface of the stem layer. The first organic layer has a first end portion and a second end portion located on a side opposite to the first end portion. A thickness of the first upper electrode immediately above the second end portion is greater than a thickness of the first upper electrode immediately above the first end portion. A thickness of the first cap layer immediately above the second end portion is greater than a thickness of the first cap layer immediately above the first end portion.

According to another embodiment, a display device comprises a substrate, a first lower electrode provided above the substrate, an inorganic insulating layer which covers a peripheral portion of the first lower electrode, a partition which has a conductive lower portion provided on the inorganic insulating layer, and an upper portion provided on the lower portion, a first organic layer which is provided on the first lower electrode and includes a first light emitting layer, a first upper electrode which is provided on the first organic layer and is in contact with the lower portion of the partition, and a first cap layer provided on the first upper electrode. The partition surrounds the first organic layer, the first upper electrode and the first cap layer. The lower portion has a bottom layer provided on the inorganic insulating layer, and a stem layer provided between the bottom layer and the upper portion. The bottom layer and the upper portion protrude from a side surface of the stem layer. The first organic layer has a first end portion and a second end portion located on a side opposite to the first end portion. A thickness of the first cap layer immediately above the second end portion is greater than a thickness of the first cap layer immediately above the first end portion. A length which protrudes from the stem layer in the bottom layer facing the second end portion is greater than a length which protrudes from the stem layer in the bottom layer facing the first end portion.

According to yet another embodiment, a manufacturing method of a display device comprises preparing a processing substrate in which a first lower electrode, a second lower electrode, a third lower electrode, an inorganic insulating layer and a partition are formed above a substrate, the inorganic insulating layer covering a peripheral portion of each of the first, second and third lower electrodes, the partition including a lower portion located on the inorganic insulating layer and an upper portion which is located on the lower portion and protrudes from a side surface of the lower portion, forming a first stacked film including a first organic layer, a first upper electrode and a first cap layer on the first lower electrode, the first organic layer including a first light emitting layer, the first upper electrode being located on the first organic layer, the first cap layer being located on the first upper electrode, forming a first sealing layer using an inorganic insulating material on the first stacked film, patterning the first stacked film and the first sealing layer, forming a second stacked film including a second organic layer, a second upper electrode and a second cap layer on the second lower electrode, the second organic layer including a second light emitting layer different from the first light emitting layer, the second upper electrode being located on the second organic layer, the second cap layer being located on the second upper electrode, forming a second sealing layer using an inorganic insulating material on the second stacked film, and patterning the second stacked film and the second sealing layer. At least one first evaporation source for forming the first cap layer and a second evaporation source for forming the second upper electrode incline with respect to a normal of the processing substrate. Evaporation directions for forming the first cap layer and the second upper electrode are same as each other.

The embodiments can provide a display device and a manufacturing method thereof such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

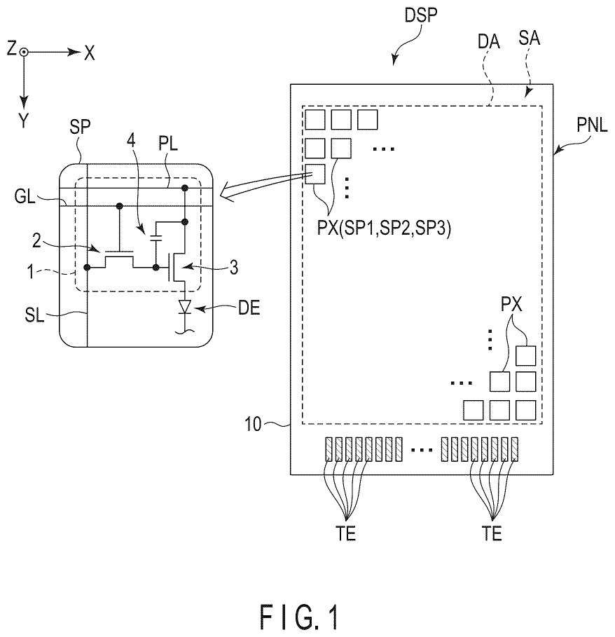

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA has a plurality of terminals TE which are arranged along one direction. In the example shown in the figure, the terminals TE are arranged in the first direction X. Each of the terminals TE extends in the second direction Y. However, the configuration is not limited to this example. For example, these terminals TE are electrically connected to a flexible printed circuit or an IC chip.

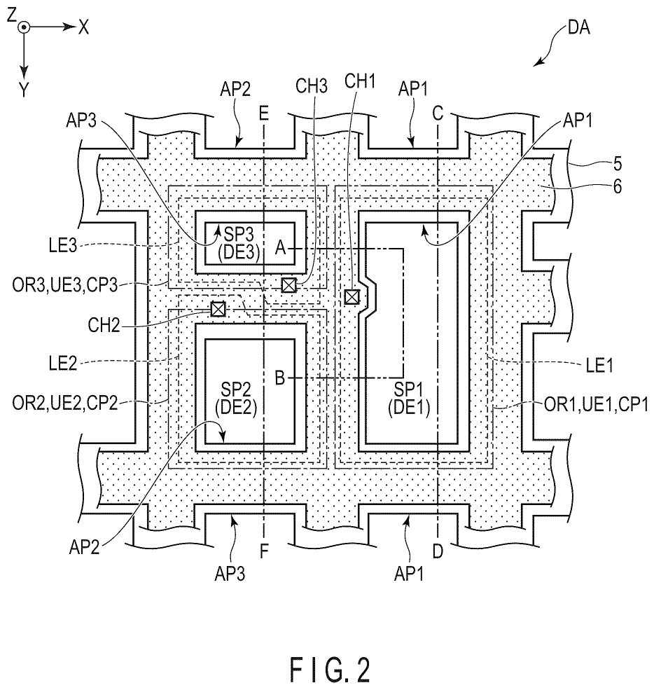

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5. The partition 6 is conductive and is electrically connected to, of the terminals TE shown in FIG. 1, the terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1, an organic layer OR1 and a cap layer CP1 overlapping the aperture AP1. The peripheral portion of the lower electrode LE1 is covered with the inorganic insulating layer 5. The lower electrode LE1, the organic layer OR1, the upper electrode UE1 and the cap layer CP1 are surrounded by the partition 6 in plan view. The peripheral portion of each of the organic layer OR1, the upper electrode UE1 and the cap layer CP1 overlaps the inorganic insulating layer 5 in plan view. The organic layer OR1 includes a light emitting layer which emits light in, for example, a blue wavelength range.

The display element DE2 of subpixel SP2 comprises a lower electrode LE2, an upper electrode UE2, an organic layer OR2 and a cap layer CP2 overlapping the aperture AP2. The peripheral portion of the lower electrode LE2 is covered with the inorganic insulating layer 5. The lower electrode LE2, the organic layer OR2, the upper electrode UE2 and the cap layer CP2 are surrounded by the partition 6 in plan view. The peripheral portion of each of the organic layer OR2, the upper electrode UE2 and the cap layer CP2 overlaps the inorganic insulating layer 5 in plan view. The organic layer OR2 includes a light emitting layer which emits light in, for example, a green wavelength range.

The display element DE3 of subpixel SP3 comprises a lower electrode LE3, an upper electrode UE3, an organic layer OR3 and a cap layer CP3 overlapping the aperture AP3. The peripheral portion of the lower electrode LE3 is covered with the inorganic insulating layer 5. The lower electrode LE3, the organic layer OR3, the upper electrode UE3 and the cap layer CP3 are surrounded by the partition 6 in plan view. The peripheral portion of each of the organic layer OR3, the upper electrode UE3 and the cap layer CP3 overlaps the inorganic insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3, the upper electrodes UE1, UE2 and UE3 and the cap layers CP1, CP2 and CP3 are shown by dash-dot lines. It should be noted that the outer shape of each of the lower electrodes, the organic layers, the upper electrodes and the cap layers shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1 in a contact hole CH1. The lower electrode LE2 is electrically connected to the pixel circuit 1 of subpixel SP2 in a contact hole CH2. The lower electrode LE3 is electrically connected to the pixel circuit 1 of subpixel SP3 in a contact hole CH3.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

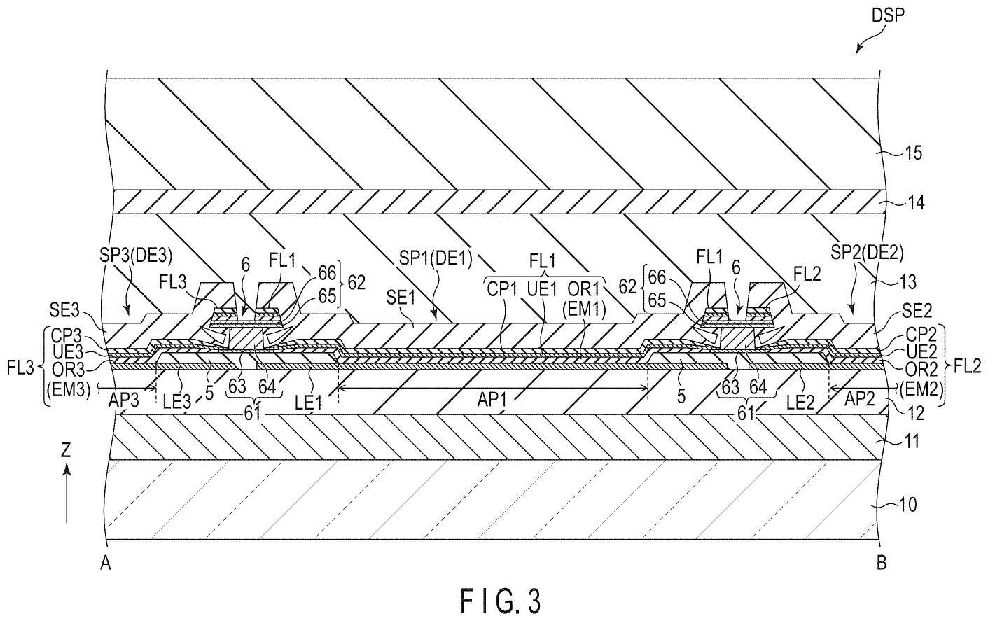

FIG. 3 is the schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2 and LE3 are connected to the pixel circuits 1 of subpixels SP1, SP2 and SP3, respectively, through the contact holes provided in the insulating layer 12. It should be noted that the contact holes of the insulating layer 12 are omitted in FIG. 3.

The partition 6 has a conductive lower portion 61 provided on the inorganic insulating layer 5, and an upper portion 62 provided on the lower portion 61.

In the example shown in the figure, the lower portion 61 has a bottom layer 63 provided on the inorganic insulating layer 5, and a stem layer 64 provided between the bottom layer 63 and the upper portion 62. The bottom layer 63 is thinner than the stem layer 64. The bottom layer 63 has a width greater than that of the stem layer 64. The both end portions of the bottom layer 63 protrude from the side surfaces of the stem layer 64.

The upper portion 62 has a first thin film 65 provided on the stem layer 64 and a second thin film 66 provided on the first thin film 65. The upper portion 62 has a width greater than that of the stem layer 64. The both end portions of the upper portion 62 protrude from the side surfaces of the stem layer 64.

In the example shown in the figure, the upper portion 62 has a width greater than that of the bottom layer 63. It should be noted that the bottom layer 63 may have a width greater than that of the upper portion 62.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

The cap layer CP1 is provided on the upper electrode UE1. The cap layer CP2 is provided on the upper electrode UE2. The cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

A sealing layer SE1 is provided on the cap layer CP1, is in contact with the partition 6 and continuously covers the members of subpixel SP1.

A sealing layer SE2 is provided on the cap layer CP2, is in contact with the partition 6 and continuously covers the members of subpixel SP2.

A sealing layer SE3 is provided on the cap layer CP3, is in contact with the partition 6 and continuously covers the members of subpixel SP3. In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

In the example shown in the figure, part of the stacked film FL1 is located on the partition 6 around subpixel SP1 and spaced apart from the stacked film FL1 located in the aperture AP1 (in other words, the portion which constitutes the display element DE1).

Similarly, part of the stacked film FL2 is located on the partition 6 around subpixel SP2 and spaced apart from the stacked film FL2 located in the aperture AP2 (in other words, the portion which constitutes the display element DE2).

Similarly, part of the stacked film FL3 is located on the partition 6 around subpixel SP3 and spaced apart from the stacked film FL3 located in the aperture AP3 (in other words, the portion which constitutes the display element DE3).

It should be noted that the stacked films FL1, FL2 and FL3 located on the partition 6 may be omitted in some cases. In these cases, a cavity is formed between the sealing layers SE1, SE2 and SE3 and the partition 6.

Each of the end portions of the sealing layers SE1, SE2 and SE3 is located above the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The partition 6 and the sealing layers SE1, SE2 and SE3 are covered with a resin layer 13. When cavities are formed between the sealing layers SE1, SE2 and SE3 and the partition 6, these cavities are filled with the resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The stem layer 64 is formed of a material which is different from the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The first thin film 65 is formed of, for example, a titanium-based material such as titanium or a titanium compound. The second thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, the insulating layer 12 and the inorganic insulating layer 5 shown in the figure are provided over the display area DA and the surrounding area SA.

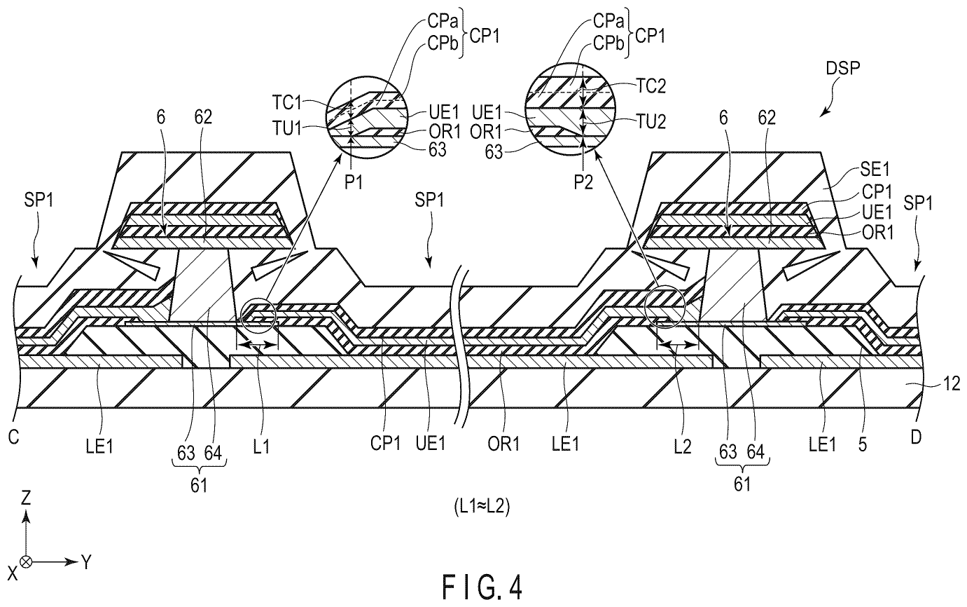

FIG. 4 is the schematic cross-sectional view of the major portion of the display device DSP along the C-D line of FIG. 2.

FIG. 4 shows the section of a plurality of subpixels SP1 which are arranged in the second direction Y. In FIG. 4, the illustrations of the substrate 10, the circuit layer 11, the resin layer 13, the sealing layer 14 and the resin layer 15 shown in FIG. 3 are omitted.

This specification focuses attention on the subpixel SP1 located at the center of the figure. The organic layer OR1 has an end portion P1 in the second direction Y, and an end portion P2 on a side opposite to the end portion P1. In FIG. 4, each of an area including the end portion P1 and an area including the end portion P2 is enlarged. In the example shown in the figure, each of the end portion P1 and the end portion P2 is located on the bottom layer 63 and is spaced apart from the stem layer 64. The end portion P1 and the end portion P2 are located immediately under the upper portions 62.

The bottom layer 63 facing the end portion P1 has length L1 which protrudes from the stem layer 64. The bottom layer 63 facing the end portion P2 has length L2 which protrudes from the stem layer 64. Length L1 is equal to length L2 (L1˜ L2).

The upper electrode UE1 overlaps the organic layer OR1, goes beyond the end portion P1 and the end portion P2 and is directly in contact with the upper surface of the bottom layer 63. In this specification, the upper surface of the bottom layer 63 is assumed to include, of the bottom layer 63, the surface which is directly in contact with the stem layer 64, and the surface which protrudes from the stem layer 64 and faces the upper portion 62. In the example shown in the figure, the upper electrode UE1 is directly in contact with the side surface of the stem layer 64 of the partition 6 facing the end portion P2. In this specification, the side surface of the stem layer 64 is assumed to be, of the stem layer 64, the surface which extends between the bottom layer 63 and the upper portion 62. The upper electrode UE1 is spaced apart from the stem layer 64 of the partition 6 facing the end portion P1. However, the upper electrode UE1 may be in contact with this stem layer 64.

When the upper electrode UE1 is spaced apart from the stem layer 64 of the partition 6 facing the end portion P1, the cap layer CP1 is directly in contact with the upper surface of the bottom layer 63. When the upper electrode UE1 is spaced apart from the stem layer 64 of the partition 6 facing the end portion P1, the upper electrode UE1 may be directly in contact with the upper surface of the bottom layer 63 or may not be in contact with the bottom layer 63.

As shown in the enlarged view of each of the area including the end portion P1 and the area including the end portion P2, in the upper electrode UE1, thickness TU2 immediately above the end portion P2 is greater than thickness TU1 immediately above the end portion P1 (TU1<TU2). The area of contact between the lower portion 61 facing the end portion P2 and the upper electrode UE1 is greater than that between the lower portion 61 facing the end portion P1 and the upper electrode UE1.

The cap layer CP1 overlaps the upper electrode UE1, goes beyond the end portion P1 and the end portion P2 and is in contact with the lower portion 61. In the example shown in the figure, the cap layer CP1 is in contact with the stem layer 64 of the partition 6 facing the end portion P2.

The cap layer CP1 is, for example, a multilayer body consisting of two layers, and has a thin film CPa located on the upper electrode UE1 and a thin film CPb located on the thin film CPa. The thin film CPa and the thin film CPb are formed of transparent materials which are different from each other, and have refractive indices which are different from each other. The thin film CPa is a high-refractive layer which has a refractive index greater than that of the upper electrode UE1. The thin film CPb is a low-refractive layer which has a refractive index less than that of the thin film CPa.

In the cap layer CP1, thickness TC2 immediately above the end portion P2 is greater than thickness TC1 immediately above the end portion P1 (TC1<TC2). In this specification, the thickness of each cap layer is the sum of the thin films constituting the multilayer body, and here, refers to the sum of the thickness of the thin film CPa and the thickness of the thin film CPb.

The multilayer body consisting of the organic layer OR1, the upper electrode UE1 and the cap layer CP1 is provided over the entire surface of the upper portion 62 of the partition 6. The sealing layer SE1 covers the cap layer CP1 and the partition 6.

In the example shown in FIG. 4, for example, the lower electrode LE1 corresponds to the first lower electrode. The organic layer OR1 corresponds to the first organic layer. The end portion P1 corresponds to the first end portion. The end portion P2 corresponds to the second end portion. Length L1 corresponds to the first length. Length L2 corresponds to the second length. The upper electrode UE1 corresponds to the first upper electrode. Thickness T1 corresponds to the first thickness. Thickness T2 corresponds to the second thickness. The cap layer CP1 corresponds to the first cap layer. The sealing layer SE1 corresponds to the first sealing layer.

It should be noted that length L1 may be different from length L2 in some cases.

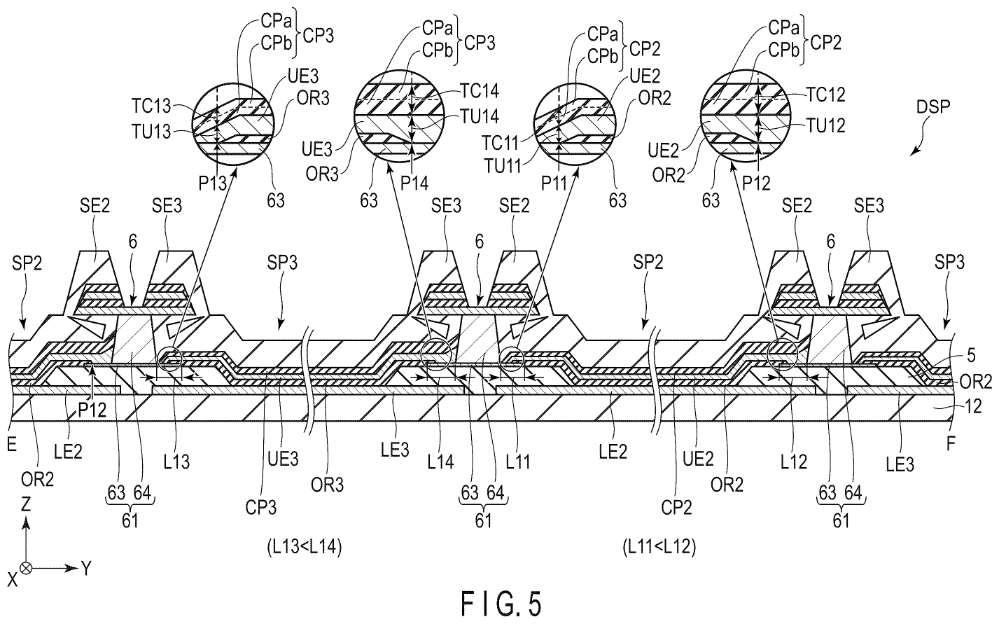

FIG. 5 is the schematic cross-sectional view of the major portion of the display device DSP along the E-F line of FIG. 2.

FIG. 5 shows the section of subpixels SP2 and SP3 which are alternately arranged in the second direction Y. In FIG. 5, the illustrations of the substrate 10, the circuit layer 11, the resin layer 13, the sealing layer 14 and the resin layer 15 shown in FIG. 3 are omitted.

First, this specification focuses attention on the subpixel SP2 located on the right side of the figure.

The organic layer OR2 has an end portion P11 in the second direction Y, and an end portion P12 on a side opposite to the end portion P11. In FIG. 5, each of an area including the end portion P11 and an area including the end portion P12 is enlarged. In the example shown in the figure, each of the end portion P11 and the end portion P12 is located on the bottom layer 63 and is spaced apart from the stem layer 64.

The bottom layer 63 facing the end portion P11 has length L11 which protrudes from the stem layer 64. The bottom layer 63 facing the end portion P12 has length L12 which protrudes from the stem layer 64. Length L11 is different from length L12. In the example shown in the figure, length L12 is greater than length L11 (L11<L12).

The upper electrode UE2 overlaps the organic layer OR2, goes beyond the end portion P11 and the end portion P12 and is directly in contact with the upper surface of the bottom layer 63. In the example shown in the figure, the upper electrode UE2 is directly in contact with the side surface of the stem layer 64 of the partition 6 facing the end portion P12. The upper electrode UE2 is spaced apart from the stem layer 64 of the partition 6 facing the end portion P11. However, the upper electrode UE2 may be in contact with this stem layer 64.

When the upper electrode UE2 is spaced apart from the stem layer 64 of the partition 6 facing the end portion P11, the cap layer CP2 is directly in contact with the upper surface of the bottom layer 63. When the upper electrode UE2 is spaced apart from the stem layer 64 of the partition 6 facing the end portion P11, the upper electrode UE2 may be directly in contact with the upper surface of the bottom layer 63 or may not be in contact with the bottom layer 63.

As shown in the enlarged view of each of the area including the end portion P11 and the area including the end portion P12, in the upper electrode UE2, thickness TU12 immediately above the end portion P12 is greater than thickness TU11 immediately above the end portion P11 (TU11<TU12). The area of contact between the lower portion 61 facing the end portion P12 and the upper electrode UE2 is greater than that between the lower portion 61 facing the end portion P11 and the upper electrode UE2.

The cap layer CP2 overlaps the upper electrode UE2, goes beyond the end portion P11 and the end portion P12 and is in contact with the lower portions 61. In the example shown in the figure, the cap layer CP2 is in contact with the stem layer 64 of the partition 6 facing the end portion P12.

In a manner similar to that of the cap layer CP1, the cap layer CP2 is, for example, a multilayer body consisting of two layers, and has a thin film CPa located on the upper electrode UE2 and a thin film CPb located on the thin film CPa. The thin film CPa and the thin film CPb are formed of transparent materials which are different from each other, and have refractive indices which are different from each other. The thin film CPa is a high-refractive layer which has a refractive index greater than that of the upper electrode UE2. The thin film CPb is a low-refractive layer which has a refractive index less than that of the thin film CPa.

In the cap layer CP2, thickness TC12 immediately above the end portion P12 is greater than thickness TC11 immediately above the end portion P11 (TC11<TC12).

The multilayer body consisting of the organic layer OR2, the upper electrode UE2 and the cap layer CP2 is provided on the upper portion 62 of the partition 6. The sealing layer SE2 covers the cap layer CP2 and the partition 6. The sealing layer SE2 is provided on the multilayer body located on the partition 6.

It should be noted that the multilayer body located on the upper portion 62 of the partition 6 may be omitted in some cases. In these cases, a cavity is formed between the upper portion 62 of the partition 6 and the sealing layer SE2.

Now, this specification focuses attention on the subpixel SP3 located on the left side of the figure.

The organic layer OR3 has an end portion P13 in the second direction Y, and an end portion P14 on a side opposite to the end portion P13. In FIG. 5, each of an area including the end portion P13 and an area including the end portion P14 is enlarged. In the example shown in the figure, each of the end portion P13 and the end portion P14 is located on the bottom layer 63 and is spaced apart from the stem layer 64.

The organic layer OR3 is located on a side opposite to the organic layer OR2 across the intervening partition 6 located at the center of the figure. The end portion P14 is located on a side opposite to the end portion P11 across the intervening partition 6. Since subpixels SP2 and SP3 are alternately arranged in the second direction Y, the organic layer OR2 and the organic layer OR3 are also alternately arranged in the second direction Y. In this array, the end portions P11, P12, P13 and P14 are arranged in this order in the second direction Y. For example, on the left side of the figure, the end portion P12 of the organic layer OR2 is located on a side opposite to the end portion P13 of the organic layer OR3 across the intervening partition 6.

The bottom layer 63 facing the end portion P13 has length L13 which protrudes from the stem layer 64. The bottom layer 63 facing the end portion P14 has length L14 which protrudes from the stem layer 64. Length L13 is different from length L14. In the example shown in the figure, length L14 is greater than length L13 (L13<L14).

The upper electrode UE3 overlaps the organic layer OR3, goes beyond the end portion P13 and the end portion P14 and is directly in contact with the upper surface of the bottom layer 63. In the example shown in the figure, the upper electrode UE3 is directly in contact with the side surface of the stem layer 64 of the partition 6 facing the end portion P14. The upper electrode UE3 is spaced apart from the stem layer 64 of the partition 6 facing the end portion P13. However, the upper electrode UE3 may be in contact with this stem layer 64.

When the upper electrode UE3 is spaced apart from the stem layer 64 of the partition 6 facing the end portion P13, the cap layer CP3 is directly in contact with the upper surface of the bottom layer 63. When the upper electrode UE3 is spaced apart from the stem layer 64 of the partition 6 facing the end portion P13, the upper electrode UE3 may be directly in contact with the upper surface of the bottom layer 63 or may not be in contact with the bottom layer 63.

As shown in the enlarged view of each of the area including the end portion P13 and the area including the end portion P14, in the upper electrode UE3, thickness TU14 immediately above the end portion P14 is greater than thickness TU13 immediately above the end portion P13 (TU13<TU14). The area of contact between the lower portion 61 facing the end portion P14 and the upper electrode UE3 is greater than that between the lower portion 61 facing the end portion P13 and the upper electrode UE3.

The cap layer CP3 overlaps the upper electrode UE3, goes beyond the end portion P13 and the end portion P14 and is in contact with the lower portion 61. In the example shown in the figure, the cap layer CP3 is in contact with the stem layer 64 of the partition 6 facing the end portion P14.

In a manner similar to that of the cap layers CP1 and CP2, the cap layer CP3 is, for example, a multilayer body consisting of two layers, and has a thin film CPa located on the upper electrode UE3 and a thin film CPb located on the thin film CPa.

For example, in the cap layer CP3, thickness TC14 immediately above the end portion P14 is different from thickness TC13 immediately above the end portion P13. In the example shown in the figure, thickness TC14 is greater than thickness TC13 (TC13<TC14). It should be noted that, regarding the cap layer CP3, when subpixel SP1, subpixel SP2 and subpixel SP3 are formed in this order, thickness TC14 may be equal to thickness TC13 in some cases.

The multilayer body consisting of the organic layer OR3, the upper electrode UE3 and the cap layer CP3 is provided on the upper portion 62 of the partition 6. The sealing layer SE3 covers the cap layer CP3 and the partition 6. The sealing layer SE3 is provided on the multilayer body located on the partition 6. On the partition 6, the sealing layer SE2 is spaced apart from the sealing layer SE3.

It should be noted that the multilayer body located on the upper portion 62 of the partition 6 may be omitted in some cases. In these cases, a cavity is formed between the upper portion 62 of the partition 6 and the sealing layer SE3.

Now, this specification focuses attention on the partition 6 located between subpixel SP2 and subpixel SP3.

In the bottom layer 63, length L14 which protrudes from the stem layer 64 toward subpixel SP3 is greater than length L11 which protrudes from the stem layer 64 toward subpixel SP2 (L14>L11).

Difference A2 between length L11 and length L12 in subpixel SP2 is different from difference Δ3 between length L13 and length L14 in subpixel SP3 (Δ2+Δ3). Difference A1 between length L1 and length L2 in subpixel SP1 shown in FIG. 4 is different from each of differences A2 and A3.

For example, in a case where subpixel SP1, subpixel SP2 and subpixel SP3 are formed in this order, the relationship of the differences could be as follows.

Δ3>Δ2>Δ1

Thickness TU14 of the upper electrode UE3 immediately above the end portion P14 is greater than thickness TU11 of the upper electrode UE2 immediately above the end portion P11 (TU14>TU11).

Thickness TC14 of the cap layer CP3 immediately above the end portion P14 is greater than thickness TC11 of the cap layer CP2 immediately above the end portion P11 (TC14>TC11).

In the example shown in FIG. 5, for example, the lower electrode LE2 corresponds to the first lower electrode, and the lower electrode LE3 corresponds to the second lower electrode. The organic layer OR2 corresponds to the first organic layer. The end portion P11 corresponds to the first end portion. The end portion P12 corresponds to the second end portion. The organic layer OR3 corresponds to the second organic layer. The end portion P13 corresponds to the third end portion. The end portion P14 corresponds to the fourth end portion. The upper electrode UE2 corresponds to the first upper electrode. The upper electrode UE3 corresponds to the second upper electrode. The cap layer CP2 corresponds to the first cap layer. The cap layer CP3 corresponds to the second cap layer. The sealing layer SE2 corresponds to the first sealing layer. The sealing layer SE3 corresponds to the second sealing layer.

Now, this specification explains an evaporation device EV for forming each upper electrode and each cap layer.

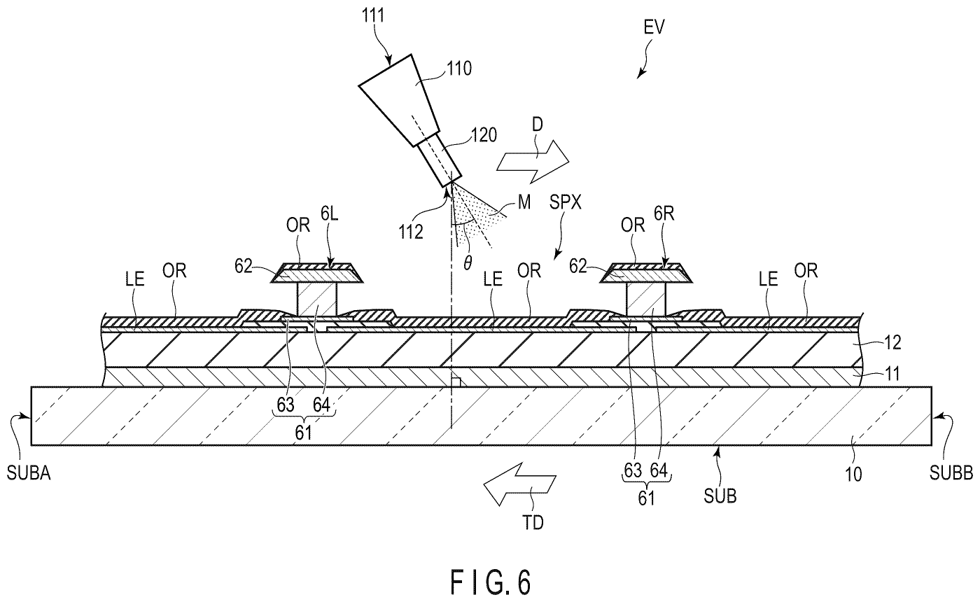

FIG. 6 is a diagram for explaining the evaporation device EV.

The evaporation device EV comprises an evaporation source 110 configured to emit a material M. The material M is a conductive material for forming each upper electrode or an insulating material for forming each cap layer.

The example shown in the figure assumes the process of forming an upper electrode. A processing substrate SUB is prepared by forming a circuit layer 11, an insulating layer 12, a lower electrode LE, an inorganic insulating layer 5, a partition 6 and an organic layer OR on a substrate 10. The processing substrate SUB has an end SUBA, and the other end SUBB on a side opposite to the end SUBA. In the example shown in the figure, the processing substrate SUB is conveyed such that the end SUBA is the leading end. The conveyance direction TD of the processing substrate SUB is shown by an arrow in the figure.

The extension direction of the evaporation source 110 is shown by the dotted line in the figure. The normal of the substrate 10 is shown by the dash-dot line in the figure. The extension direction of the evaporation source 110 inclines with respect to the normal of the substrate 10. Here, the extension direction is, for example, the direction in which a nozzle 120 controlling the emission direction of the material M extends. The evaporation direction D of the material M by the evaporation source 110 is shown by an arrow in the figure. The evaporation direction D is the direction from the bottom portion 111 of the evaporation source 110 to the opening portion 112 of the nozzle 120. In other words, the bottom portion 111 is located on the upstream side of the evaporation direction D, and the opening portion 112 is located on the downstream side of the evaporation direction D. When the arrow indicating the evaporation direction D points right as shown in the figure, the material M is emitted from the left side of the figure to the right side. In the example shown in the figure, the evaporation direction D is the opposite direction of the conveyance direction TD. However, the evaporation direction D may be the same direction as the conveyance direction TD.

In this evaporation source EV, the evaporation source 110 is fixed, and emits the material M. The material M emitted from the evaporation source 110 is deposited on the processing substrate SUB while the processing substrate SUB is conveyed such that the end SUBA is the leading end and the partition 6 is used as a mask.

As another example of the evaporation device EV, the evaporation source 110 may be configured to be movable while emitting the material M. In such an evaporation device EV, the material M is deposited on the processing substrate SUB as the evaporation source 110 emits the material M to the fixed processing substrate SUB while moving.

As yet another example of the evaporation device EV, the evaporation source 110 may move while emitting the material M, and the processing substrate may be conveyed.

In other words, the upper electrode or the cap layer is formed as the material M emitted from the evaporation source 110 is deposited on the processing substrate SUB while the relative position of the processing substrate SUB and the evaporation source 110 is changed in the evaporation device EV.

When the evaporation direction D is the direction from left to right as shown in the figure, in the subpixel SPX located at the center of the figure, the material M is not easily deposited near the left partition 6L, and the material M is easily deposited near the right partition 6R. For this reason, the thickness of the material M deposited near the partition 6R is greater than that of the material M deposited near the partition 6L.

By this process, the upper electrode UE1 having thicknesses TU1 and TU2 and the cap layer CP1 having thicknesses TC1 and TC2 as explained with reference to FIG. 4 are formed. Further, the upper electrode UE2 having thicknesses TU11 and TU12, the cap layer CP2 having thicknesses TC11 and TC12, the upper electrode UE3 having thicknesses TU13 and TU14 and the cap layer CP3 having thicknesses TC13 and TC14 as explained with reference to FIG. 5 are formed.

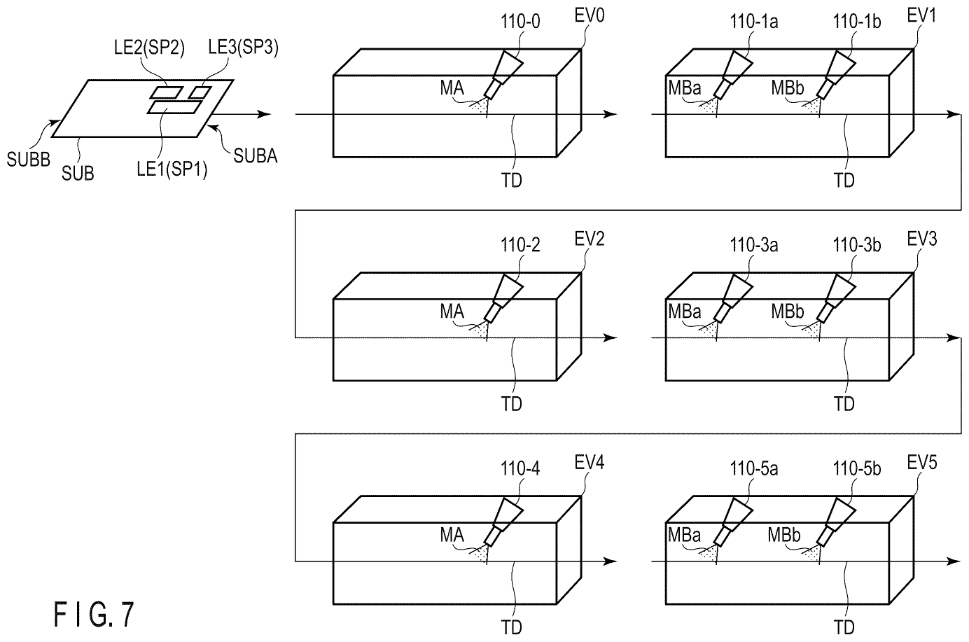

FIG. 7 is a diagram for explaining the vapor deposition of each upper electrode and each cap layer. In the following explanation, it is assumed that subpixel SP1, subpixel SP2 and subpixel SP3 are formed in this order.

The processing substrate SUB is conveyed such that the end SUBA is the leading end. The conveyance direction TD of the processing substrate SUB is parallel to the direction in which the lower electrode LE2 of subpixel SP2 and the lower electrode LE3 of subpixel SP3 are arranged (in other words, the second direction Y shown in FIG. 2 etc.).

First, the processing substrate SUB is carried in an evaporation device EV0. In the evaporation device EV0, an evaporation source 110-0 inclines and emits a material MA toward the processing substrate SUB in an oblique direction. The material MA is a mixture of magnesium and silver. The upper electrode UE1 is formed as the material MA is deposited on the processing substrate SUB.

Subsequently, the processing substrate SUB is carried in an evaporation device EV1. In the evaporation device EV1, an evaporation source 110-1a and an evaporation source 110-1b incline. The evaporation source 110-1a emits a material MBa toward the processing substrate SUB in an oblique direction. The material MBa is a high-refractive material which is transparent. The thin film CPa of the cap layer CP1 is formed as the material MBa is deposited on the processing substrate SUB.

Subsequently, in the evaporation device EV1, the evaporation source 110-1b emits a material MBb toward the processing substrate SUB in an oblique direction. The material MBb is a low-refractive material which is transparent. As the material MBb is deposited on the processing substrate SUB, the thin film CPb of the cap layer CP1 is formed. It should be noted that, in the evaporation device EV1, the evaporation source 110-1a and the evaporation source 110-1b are accommodated in different chambers and are configured such that the material MBa and the material MBb are not mixed with each other.

Subsequently, the sealing layer SE1 is formed. After the formation of the sealing layer SE1, the stacked film FL1 and the sealing layer SE1 are patterned. The details are described later.

Subsequently, the processing substrate SUB is carried in an evaporation device EV2. In the evaporation device EV2, an evaporation source 110-2 inclines and emits a material MA toward the processing substrate SUB in an oblique direction. The upper electrode UE2 is formed as the material MA is deposited on the processing substrate SUB.

Subsequently, the processing substrate SUB is carried in an evaporation device EV3. In the evaporation device EV3, an evaporation source 110-3a and an evaporation source 110-3b incline. The evaporation source 110-3a emits a material MBa toward the processing substrate SUB in an oblique direction. The thin film CPa of the cap layer CP2 is formed as the material MBa is deposited on the processing substrate SUB.

Subsequently, in the evaporation device EV3, the evaporation source 110-3b emits a material MBb toward the processing substrate SUB in an oblique direction. As the material MBb is deposited on the processing substrate SUB, the thin film CPb of the cap layer CP2 is formed. In the evaporation device EV3, the evaporation source 110-3a and the evaporation source 110-3b are accommodated in different chambers.

Subsequently, the sealing layer SE2 is formed. After the formation of the sealing layer SE2, the stacked film FL2 and the sealing layer SE2 are patterned.

Subsequently, the processing substrate SUB is carried in an evaporation device EV4. In the evaporation device EV4, an evaporation source 110-4 inclines and emits a material MA toward the processing substrate SUB in an oblique direction. The upper electrode UE3 is formed as the material MA is deposited on the processing substrate SUB.

Subsequently, the processing substrate SUB is carried in an evaporation device EV5. In the evaporation device EV5, an evaporation source 110-5a and an evaporation source 110-5b incline. The evaporation source 110-5a emits a material MBa toward the processing substrate SUB in an oblique direction. The thin film CPa of the cap layer CP3 is formed as the material MBa is deposited on the processing substrate SUB.

Subsequently, in the evaporation device EV5, the evaporation source 110-5b emits a material MBb toward the processing substrate SUB in an oblique direction. As the material MBb is deposited on the processing substrate SUB, the thin film CPb of the cap layer CP3 is formed. In the evaporation device EV5, the evaporation source 110-5a and the evaporation source 110-5b are accommodated in different chambers.

Subsequently, the sealing layer SE3 is formed. After the formation of the sealing layer SE3, the stacked film FL3 and the sealing layer SE3 are patterned.

In the example shown in FIG. 7, all of the evaporation sources shown in the figure incline in the same direction while the processing substrate SUB is consistently conveyed such that the end SUBA is the leading end.

It should be noted that at least one of the evaporation source 110-1a and the evaporation source 110-1b should incline in the same direction as the evaporation source 110-2. In this configuration, the evaporation direction for forming the cap layer CP1 is the same as the evaporation direction for forming the upper electrode UE2.

It should be noted that at least one of the evaporation source 110-3a and the evaporation source 110-3b should incline in the same direction as the evaporation source 110-4. In this configuration, the evaporation direction for forming the cap layer CP2 is the same as the evaporation direction for forming the upper electrode UE3.

The evaporation source 110-5a or the evaporation source 110-5b may not incline.

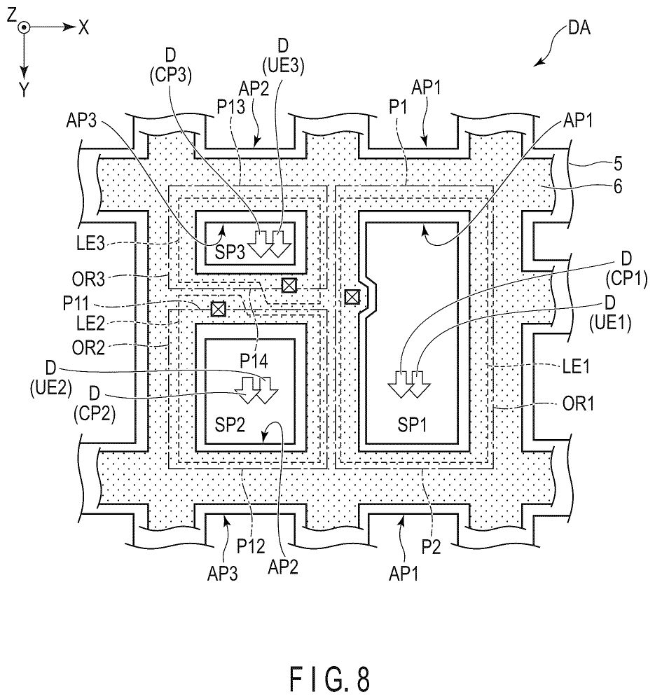

FIG. 8 is a diagram for explaining an example of the evaporation direction D when an upper electrode and a cap layer are formed in each subpixel. The example shown in FIG. 8 corresponds to a case where each upper electrode and each cap layer are formed through the process shown in FIG. 7.

In subpixel SP1, the evaporation directions D for forming the upper electrode UE1 and the cap layer CP1 on the organic layer OR1 are shown by arrows in the figure. The end portion P1 of the organic layer OR1 is located on the upstream side of the evaporation directions D. The end portion P2 of the organic layer OR1 is located on the downstream side of the evaporation directions D.

Near the end portion P1, the material for forming the upper electrode UE1 or the cap layer CP1 is not easily deposited because of the effect of the partition 6. To the contrary, near the end portion P2, the material for forming each of the upper electrode UE1 and the cap layer CP1 goes into the lower side of the partition 6. Thus, the upper electrode UE1 and the partition 6 can be electrically connected to each other. Near the end portion P2, the thick cap layer CP1 is formed immediately above the bottom layer.

In subpixel SP2, the evaporation directions D for forming the upper electrode UE2 and the cap layer CP2 on the organic layer OR2 are shown by arrows in the figure. The end portion P11 of the organic layer OR2 is located on the upstream side of the evaporation directions D. The end portion P12 of the organic layer OR2 is located on the downstream side of the evaporation directions D.

Near the end portion P11, the material for forming the upper electrode UE2 or the cap layer CP2 is not easily deposited because of the effect of the partition 6. To the contrary, near the end portion P12, the material for forming each of the upper electrode UE2 and the cap layer CP2 goes into the lower side of the partition 6. Thus, the upper electrode UE2 and the partition 6 can be electrically connected to each other. Near the end portion P12, the thick cap layer CP2 is formed immediately above the bottom layer.

In subpixel SP3, the evaporation directions D for forming the upper electrode UE3 and the cap layer CP3 on the organic layer OR3 are shown by arrows in the figure. The end portion P13 of the organic layer OR3 is located on the upstream side of the evaporation directions D. The end portion P14 of the organic layer OR3 is located on the downstream side of the evaporation directions D.

Near the end portion P13, the material for forming the upper electrode UE3 or the cap layer CP3 is not easily deposited because of the effect of the partition 6. To the contrary, near the end portion P14, the material for forming each of the upper electrode UE3 and the cap layer CP3 goes into the lower side of the partition 6. Thus, the upper electrode UE3 and the partition 6 can be electrically connected to each other. Near the end portion P14, the thick cap layer CP3 is formed immediately above the bottom layer.

The evaporation directions D for forming the cap layer CP1 and the upper electrode UE2 are the same as each other. Further, the evaporation directions D for forming the cap layer CP2 and the upper electrode UE3 are the same as each other. In the example shown in the figure, the evaporation directions D are substantially parallel to the second direction Y in which subpixels SP2 and SP3 are arranged. The both end portions P1 and P2 of the organic layer OR1 are located in the both end portions of subpixel SP1 in the second direction Y. The both end portions P11 and P12 of the organic layer OR2 are located in the both end portions of subpixel SP2 in the second direction Y. The both end portions P13 and P14 of the organic layer OR3 are located in the both end portions of subpixel SP3 in the second direction Y.

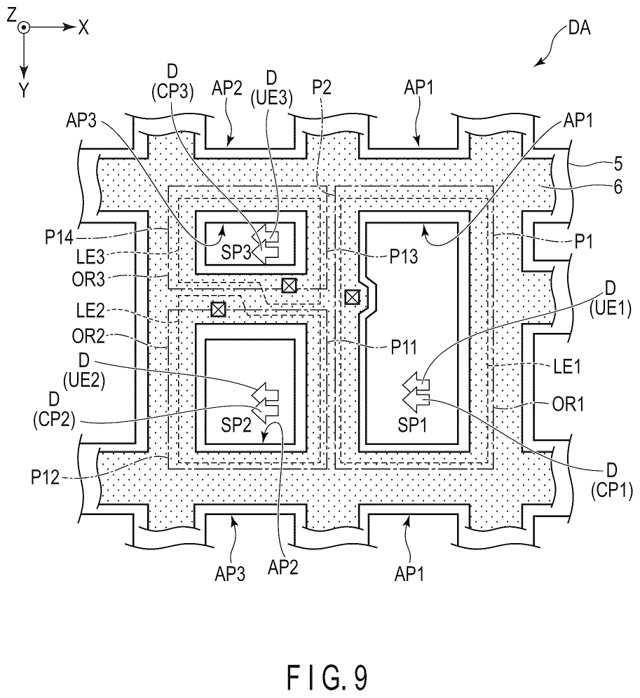

FIG. 9 is a diagram for explaining another example of the evaporation direction D when an upper electrode and a cap layer are formed in each subpixel.

The example shown in FIG. 9 is different from that shown in FIG. 8 in respect that the evaporation directions D for forming the upper electrodes UE1, UE2 and UE3 and the cap layers CP1, CP2 and CP3 are almost parallel to the first direction X.

The both end portions P1 and P2 of the organic layer OR1 are located in the both end portions of subpixel SP1 in the first direction X. Near the end portion P2 located on the downstream side of the evaporation direction D, the material for forming each of the upper electrode UE1 and the cap layer CP1 goes into the lower side of the partition 6. Thus, the upper electrode UE1 and the partition 6 can be electrically connected to each other. Near the end portion P2, the thick cap layer CP1 is formed immediately above the bottom layer.

The both end portions P11 and P12 of the organic layer OR2 are located in the both end portions of subpixel SP2 in the first direction X. Near the end portion P12 located on the downstream side of the evaporation direction D, the material for forming each of the upper electrode UE2 and the cap layer CP2 goes into the lower side of the partition 6. Thus, the upper electrode UE2 and the partition 6 can be electrically connected to each other. Near the end portion P12, the thick cap layer CP2 is formed immediately above the bottom layer.

The both end portions P13 and P14 of the organic layer OR3 are located in the both end portions of subpixel SP3 in the first direction X. Near the end portion P14 located on the downstream side of the evaporation direction D, the material for forming each of the upper electrode UE3 and the cap layer CP3 goes into the lower side of the partition 6. Thus, the upper electrode UE3 and the partition 6 can be electrically connected to each other. Near the end portion P14, the thick cap layer CP3 is formed immediately above the bottom layer.

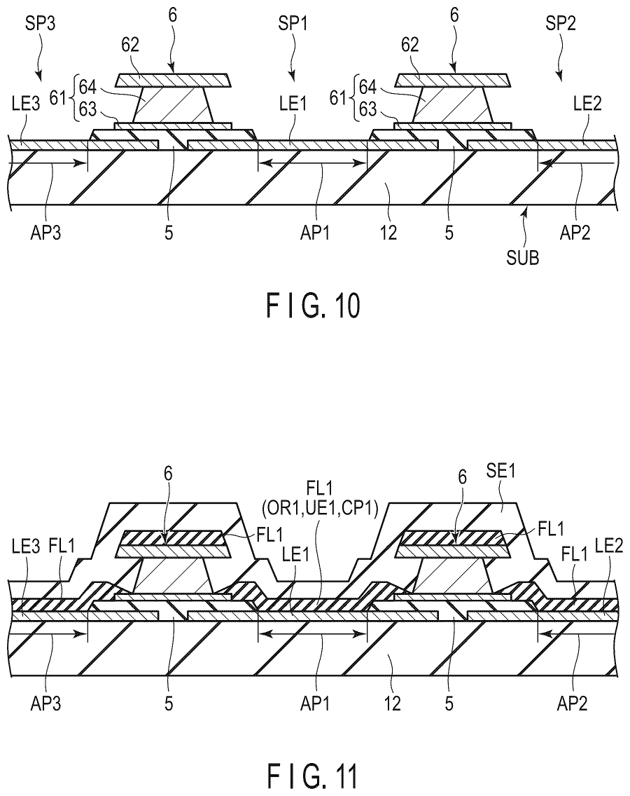

Now, this specification explains the manufacturing method of the display device DSP. Regarding each figure for explaining the manufacturing method, the illustration of the lower side of the insulating layer 12 is omitted. FIG. 10 to FIG. 15 which are referred to in the following explanation correspond to the section taken along the A-B line of FIG. 2.

First, as shown in FIG. 10, a processing substrate SUB comprising the lower electrodes LE1, LE2 and LE3, the inorganic insulating layer 5 and the partition 6 is prepared. The process of preparing the processing substrate SUB includes the following processes. The circuit layer 11 and the insulating layer 12 are formed over the display area DA and the surrounding area SA on the substrate 10. Subsequently, the lower electrode LE1 of subpixel SP1, the lower electrode LE2 of subpixel SP2 and the lower electrode LE3 of subpixel SP3 are formed on the insulating layer 12. Subsequently, the inorganic insulating layer 5 which covers the peripheral portions of the lower electrodes LE1, LE2 and LE3 is formed. Subsequently, the partition 6 which has the lower portion 61 located on the inorganic insulating layer 5 and the upper portion 62 located on the lower portion 61 is formed. The bottom layer 63 of the lower portion 61 and the upper portion 62 protrude from the side surfaces of the stem layer 64 of the lower portion 61. The bottom layer 63 is formed of a titanium-based material, and the stem layer 64 is formed of an aluminum-based material.

It should be noted that the process of forming the apertures AP1, AP2 and AP3 in the inorganic insulating layer 5 may be performed either before the partition 6 is formed or after the partition 6 is formed.

Subsequently, the display element DE1 is formed.

First, as shown in FIG. 11, the stacked film FL1 including the organic layer OR1, the upper electrode UE1 and the cap layer CP1 is formed. The process of forming the stacked film FL1 includes the process of forming the organic layer OR1 on the lower electrode LE1 in the aperture AP1, the process of forming the upper electrode UE1 which covers the organic layer OR1 and is in contact with the lower portion 61 of the partition 6, and the process of forming the cap layer CP1 on the upper electrode UE1. The process of forming the organic layer OR1 includes the process of forming each of the hole injection layer, the hole transport layer, the electron blocking layer, the light emitting layer EM1, the hole blocking layer, the electron transport layer, the electron injection layer and the like. The upper electrode UE1 is formed of a mixture of magnesium and silver.

Each of the organic layer OR1, the upper electrode UE1 and the cap layer CP1 is formed by vapor deposition using the partition 6 as a mask. In particular, the upper electrode UE1 is formed by depositing the material MA emitted from the evaporation source 110-0 which inclines with respect to the normal of the processing substrate SUB in the evaporation device EV0 shown in FIG. 7. The cap layer CP1 is formed by depositing the material MBa emitted from the evaporation source 110-1a which inclines with respect to the normal of the processing substrate SUB and the material MBb emitted from the evaporation source 110-1b in series in the evaporation device EV1 shown in FIG. 7.

The stacked film FL1 is divided into a plurality of portions by the partition 6 having an overhang shape. These organic layer OR1, the upper electrode UE1 and the cap layer CP1 are continuously formed while maintaining a vacuum environment. This stacked film FL1 is formed on the lower electrode LE2 and the lower electrode LE3 as well.

Subsequently, the sealing layer SE1 is formed on the stacked film FL1 by depositing an inorganic insulating material. The sealing layer SE1 is formed by chemical vapor deposition (CVD). The sealing layer SE1 continuously covers the portions into which the stacked film FL1 is divided, and the partition 6.

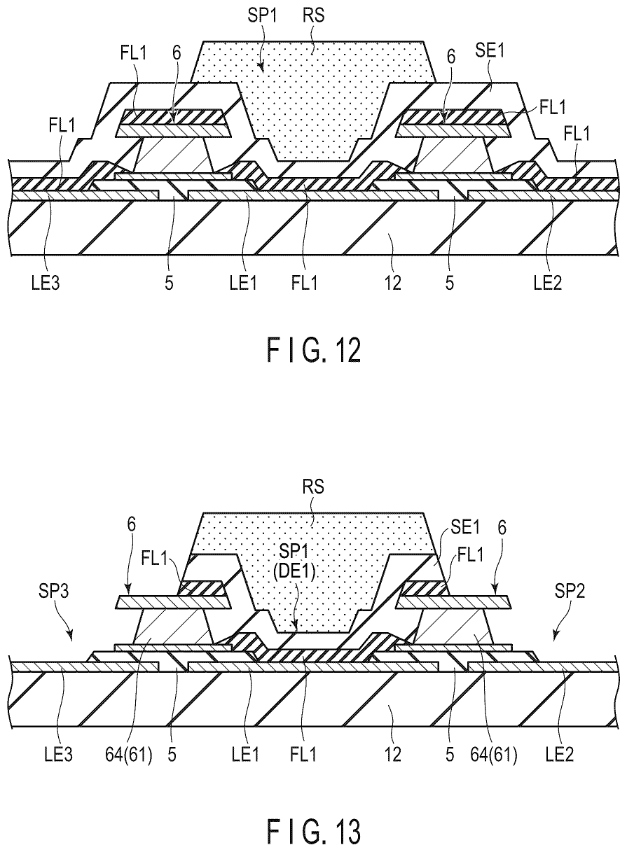

Subsequently, the sealing layer SE1 and the stacked film FL1 are patterned. First, as shown in FIG. 12, a resist RS patterned into a predetermined shape is formed on the sealing layer SE1. The resist RS overlaps subpixel SP1 and part of the partition 6 around subpixel SP1.

Subsequently, as shown in FIG. 13, etching is performed using the resist RS as a mask. Thus, the sealing layer SE1 exposed from the resist RS is removed by performing dry etching using the resist RS as a mask. Subsequently, the stacked film FL1 exposed from the resist RS is removed. At this time, in the stacked film FL1, the cap layer CP1, the upper electrode UE1 and the organic layer OR1 are removed in this order. By this process, the stacked film FL1 covered with the resist RS is left in subpixel SP1. Further, the upper portion 62 of the partition 6 is partly exposed, and the lower electrode LE2 and the lower electrode LE3 are exposed.

Subsequently, the resist RS is removed. By this process, the display element DE1 is formed in subpixel SP1.

In the process of removing each of the sealing layer SE1 and the stacked film FL1 and further removing the resist RS, the stacked film FL1 located on the upper portion 62 of the partition 6 may be removed in some cases. In these cases, a cavity is formed between the upper portion 62 and the sealing layer SE1.

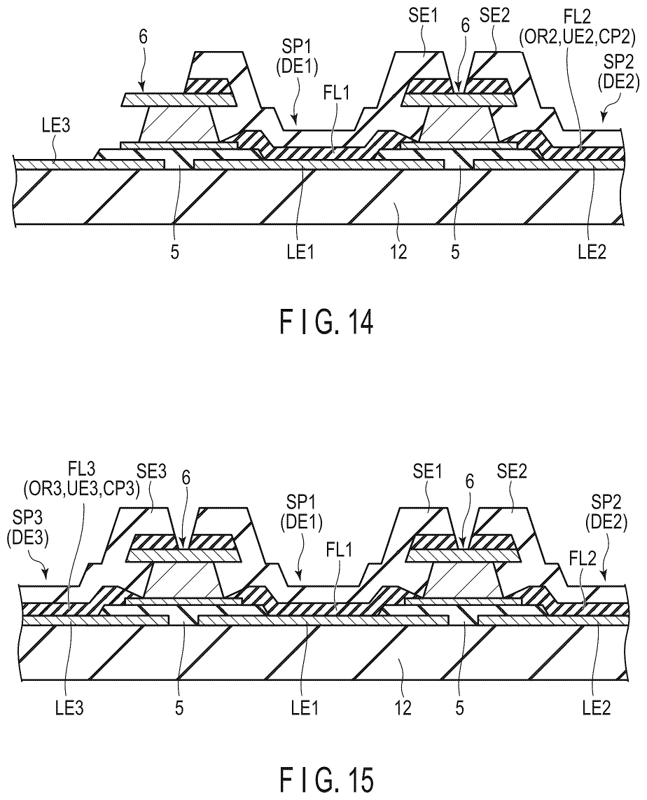

Subsequently, as shown in FIG. 14, the display element DE2 is formed. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. At this time, the upper electrode UE2 is formed by depositing the material MA emitted from the evaporation source 110-2 which inclines with respect to the normal of the processing substrate SUB in the evaporation device EV2 shown in FIG. 7. The cap layer CP2 is formed by depositing the material MBa emitted from the evaporation source 110-3a which inclines with respect to the normal of the processing substrate SUB and the material MBb emitted from the evaporation source 110-3b in series in the evaporation device EV3 shown in FIG. 7.

Subsequently, the sealing layer SE2 is formed on the stacked film FL2. Subsequently, a resist is formed on the sealing layer SE2. The sealing layer SE2 and the stacked film FL2 (the cap layer CP2, the upper electrode UE2 and the organic layer OR2) are patterned by etching using the resist as a mask. After this patterning, the resist is removed. In this manner, the display element DE2 is formed in subpixel SP2, and the lower electrode LE3 of subpixel SP3 is exposed. It should be noted that, in the process of removing each of the sealing layer SE2 and the stacked film FL2 and further removing the resist, the stacked film FL2 located on the upper portion 62 of the partition 6 may be removed in some cases. In these cases, a cavity is formed between the upper portion 62 and the sealing layer SE2.

Subsequently, as shown in FIG. 15, the display element DE3 is formed. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. At this time, the upper electrode UE3 is formed by depositing the material MA emitted from the evaporation source 110-4 which inclines with respect to the normal of the processing substrate SUB in the evaporation device EV4 shown in FIG. 7. The cap layer CP3 is formed by depositing the material MBa emitted from the evaporation source 110-5a which inclines with respect to the normal of the processing substrate SUB and the material MBb emitted from the evaporation source 110-5b in series in the evaporation device EV5 shown in FIG. 7.

Subsequently, the sealing layer SE3 is formed on the stacked film FL3. Subsequently, a resist is formed on the sealing layer SE3. The sealing layer SE3 and the stacked film FL3 (the cap layer CP3, the upper electrode UE3 and the organic layer OR3) are patterned by etching using the resist as a mask. After this patterning, the resist is removed. By this process, the display element DE3 is formed in subpixel SP3. It should be noted that, in the process of removing each of the sealing layer SE3 and the stacked film FL3 and further removing the resist, the stacked film FL3 located on the upper portion 62 of the partition 6 may be removed in some cases. In these cases, a cavity is formed between the upper portion 62 and the sealing layer SE3.

Subsequently, the resin layer 13, the sealing layer 14 and the resin layer 15 shown in FIG. 3 are formed in order. By this process, the display device DSP is completed.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

In a case where each of the cap layers CP1, CP2 and CP3 is formed by the evaporation device EV explained with reference to FIG. 6, as described above, the thickness differs between the vicinities of the both end portions of each of the cap layers. For example, in a case where the thickness near an end portion of a cap layer is extremely thin, or the bottom layer is exposed from a cap layer, when each of the sealing layers SE1 and SE2 is removed by dry etching, the cap layer may not be able to exert the function as an etching stopper, and thus, there is a possibility that the bottom layer is damaged. This respect is specifically explained with reference to drawings.

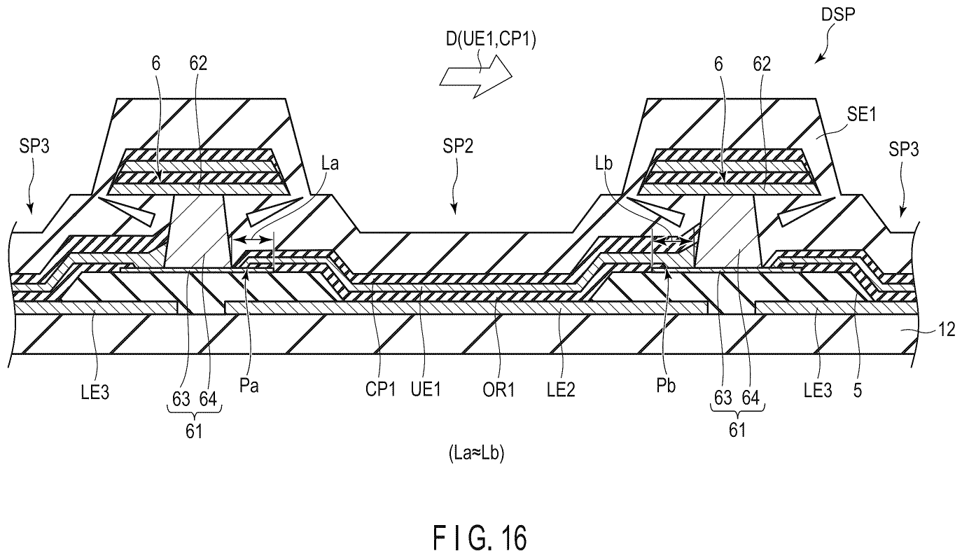

FIG. 16 is a cross-sectional view of subpixels SP2 and SP3 in which the stacked film FL1 is formed.

The evaporation direction D for forming each of the upper electrode UE1 and the cap layer CP1 is the direction from left to right in the figure, and the direction from an end portion Pa of the organic layer OR1 formed in subpixel SP2 to the other end portion Pb of the organic layer OR1.

Immediately after the stacked film FL1 is formed, length La which protrudes from the stem layer 64 in the bottom layer 63 which faces the end portion Pa is substantially equal to length Lb which protrudes from the stem layer 64 in the bottom layer 63 which faces the end portion Pb. The thickness of the upper electrode UE1 which covers the end portion Pa is less than that of the upper electrode UE1 which covers the end portion Pb. The thickness of the cap layer CP1 located immediately above the end portion Pa is less than that of the cap layer CP1 which covers the end portion Pb.

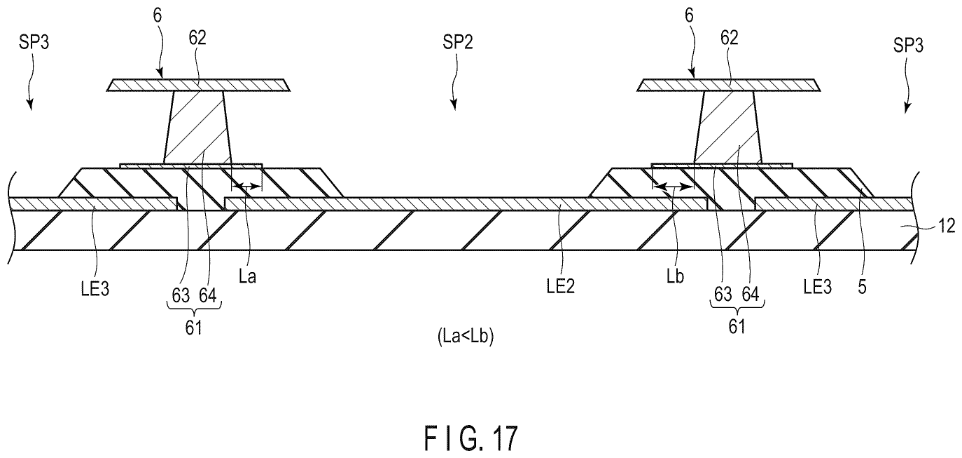

FIG. 17 is a cross-sectional view of subpixels SP2 and SP3 from which the stacked film FL1 has been removed.

In the stacked film FL1, for example, the etching rate of the cap layer CP1 at the time of removing the sealing layer SE1 is less than that of the sealing layer SE1. Therefore, the cap layer CP1 functions as an etching stopper when the sealing layer SE1 is removed. However, when the thickness of the cap layer CP1 located immediately above the end portion Pa is extremely less, or the bottom layer 63 is exposed from the cap layer CP1, the bottom layer 63 is damaged, thereby decreasing the thickness of the bottom layer 63, and further, the bottom layer 63 is partly removed. In the example shown in the figure, the left bottom layer 63 is damaged and retracted. To the contrary, the cap layer CP1 located immediately above the end portion Pb is thick, exerts the function as an etching stopper and protects the bottom layer 63. Thus, length La of the bottom layer 63 shown on the left side of the figure is less than length Lb of the bottom layer 63 shown on the right side of the figure.

In such a subpixel SP2, when the stacked film FL2 is subsequently formed, the evaporation direction D of the upper electrode UE2 is the same as the evaporation direction D of the cap layer CP1. Therefore, the upper electrode UE2 is in contact with the bottom layer 63 having length Lb substantially without being damaged in subpixel SP2. This configuration can prevent the defective connection between the upper electrode UE2 and the partition 6. Thus, compared to a case where the evaporation direction of the upper electrode UE2 is the opposite direction of the evaporation direction of the cap layer CP1, the reduction in reliability can be prevented. Although omitted in the figure, in the stacked film FL2, for example, the etching rate of the cap layer CP2 at the time of removing the sealing layer SE2 is less than that of the sealing layer SE2. Therefore, the cap layer CP2 functions as an etching stopper when the sealing layer SE2 is removed. The cap layer CP2 protects the bottom layer 63 connected to the upper electrode UE3 in subpixel SP3.

In subpixel SP3, when the stacked film FL3 is formed, the evaporation direction D of the upper electrode UE3 is the same as the evaporation direction D of the cap layer CP2. Therefore, the upper electrode UE3 is in contact with the bottom layer 63 which is not substantially damaged in subpixel SP3. This configuration can prevent the defective connection between the upper electrode UE3 and the partition 6. Thus, compared to a case where the evaporation direction of the upper electrode UE3 is the opposite direction of the evaporation direction of the cap layer CP2, the reduction in reliability can be prevented.

As described above, in a case where subpixel SP1, subpixel SP2 and subpixel SP3 are formed in order, the evaporation directions of the cap layer CP1 and the upper electrode UE2 are the same as each other, and the evaporation directions of the cap layer CP2 and the upper electrode UE3 are the same as each other. In other words, the upper electrode of the subpixel which is formed secondly and the cap layer of the subpixel which is formed firstly are formed in the same evaporation direction. The upper electrode of the subpixel which is formed thirdly and the cap layer of the subpixel which is formed secondly are formed in the same evaporation direction. By this configuration, each upper electrode can be assuredly connected to the bottom layer protected by a corresponding cap layer.

In the manufacturing method described above, for example, the lower electrode LE1 corresponds to the first lower electrode. The lower electrode LE2 corresponds to the second lower electrode. The lower electrode LE3 corresponds to the third lower electrode. The organic layer OR corresponds to the first organic layer. The light emitting layer EM1 corresponds to the first light emitting layer. The organic layer OR2 corresponds to the second organic layer. The light emitting layer EM2 corresponds to the second light emitting layer. The organic layer OR3 corresponds to the third organic layer. The light emitting layer EM3 corresponds to the third light emitting layer. The upper electrode UE1 corresponds to the first upper electrode. The upper electrode UE2 corresponds to the second upper electrode. The upper electrode UE3 corresponds to the third upper electrode. The cap layer CP1 corresponds to the first cap layer. The cap layer CP2 corresponds to the second cap layer. The cap layer CP3 corresponds to the third cap layer. The sealing layer SE1 corresponds to the first sealing layer. The sealing layer SE2 corresponds to the second sealing layer. The sealing layer SE3 corresponds to the third sealing layer. The stacked film FL1 corresponds to the first stacked film. The stacked film FL2 corresponds to the second stacked film. The stacked film FL3 corresponds to the third stacked film. The evaporation sources 110-1a and 110-1b correspond to the first evaporation source. The evaporation source 110-2 corresponds to the second evaporation source. The evaporation sources 110-3a and 110-3b correspond to the third evaporation source. The evaporation source 110-4 corresponds to the fourth evaporation source.

As explained above, the present embodiment can provide a display device and a manufacturing method thereof such that the reduction in reliability can be prevented.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
a first lower electrode provided above the substrate;
an inorganic insulating layer which covers a peripheral portion of the first lower electrode;
a partition which has a conductive lower portion provided on the inorganic insulating layer, and an upper portion provided on the lower portion;
a first organic layer which is provided on the first lower electrode and includes a first light emitting layer;
a first upper electrode which is provided on the first organic layer and is in contact with the lower portion of the partition; and
a first cap layer provided on the first upper electrode, wherein
the partition surrounds the first organic layer, the first upper electrode and the first cap layer,
the lower portion has a bottom layer provided on the inorganic insulating layer, and a stem layer provided between the bottom layer and the upper portion,
the bottom layer and the upper portion protrude from a side surface of the stem layer,
the first organic layer has a first end portion and a second end portion located on a side opposite to the first end portion,
a thickness of the first upper electrode immediately above the second end portion is greater than a thickness of the first upper electrode immediately above the first end portion, and
a thickness of the first cap layer immediately above the second end portion is greater than a thickness of the first cap layer immediately above the first end portion.

2. The display device of claim 1, wherein
a length which protrudes from the stem layer in the bottom layer facing the second end portion is different from a length which protrudes from the stem layer in the bottom layer facing the first end portion.

3. The display device of claim 1, wherein
a length which protrudes from the stem layer in the bottom layer facing the second end portion is equal to a length which protrudes from the stem layer in the bottom layer facing the first end portion.

4. The display device of claim 1, further comprising:
a second lower electrode which has a peripheral portion covered with the inorganic insulating layer;
a second organic layer which is provided on the second lower electrode and includes a second light emitting layer formed of a material different from the first light emitting layer;
a second upper electrode which is provided on the second organic layer and is in contact with the lower portion of the partition; and
a second cap layer provided on the second upper electrode, wherein
the partition surrounds the second organic layer, the second upper electrode and the second cap layer,
the second organic layer has a third end portion, and a fourth end portion located on a side opposite to the third end portion, and
a thickness of the second upper electrode immediately above the fourth end portion is greater than a thickness of the second upper electrode immediately above the third end portion.

5. The display device of claim 4, wherein
a length which protrudes from the stem layer in the bottom layer facing the fourth end portion is greater than a length which protrudes from the stem layer in the bottom layer facing the third end portion.

6. The display device of claim 4, wherein
a thickness of the second cap layer immediately above the fourth end portion is different from a thickness of the second cap layer immediately above the third end portion.

7. The display device of claim 1, further comprising a first sealing layer which covers the first cap layer and the partition and is formed of an inorganic insulating material.

8. The display device of claim 4, further comprising:
a first sealing layer which covers the first cap layer and the partition and is formed of an inorganic insulating material; and
a second sealing layer which covers the second cap layer and the partition and is formed of an inorganic insulating material, wherein
the first sealing layer is spaced apart from the second sealing layer on the partition.

9. A display device comprising:
a substrate;
a first lower electrode provided above the substrate;
an inorganic insulating layer which covers a peripheral portion of the first lower electrode;
a partition which has a conductive lower portion provided on the inorganic insulating layer, and an upper portion provided on the lower portion;
a first organic layer which is provided on the first lower electrode and includes a first light emitting layer;
a first upper electrode which is provided on the first organic layer and is in contact with the lower portion of the partition; and
a first cap layer provided on the first upper electrode, wherein
the partition surrounds the first organic layer, the first upper electrode and the first cap layer,
the lower portion has a bottom layer provided on the inorganic insulating layer, and a stem layer provided between the bottom layer and the upper portion,
the bottom layer and the upper portion protrude from a side surface of the stem layer,
the first organic layer has a first end portion and a second end portion located on a side opposite to the first end portion,
a thickness of the first cap layer immediately above the second end portion is greater than a thickness of the first cap layer immediately above the first end portion, and
a length which protrudes from the stem layer in the bottom layer facing the second end portion is greater than a length which protrudes from the stem layer in the bottom layer facing the first end portion.

10. The display device of claim 9, further comprising:
a second lower electrode which has a peripheral portion covered with the inorganic insulating layer;
a second organic layer which is provided on the second lower electrode and includes a second light emitting layer formed of a material different from the first light emitting layer;
a second upper electrode which is provided on the second organic layer and is in contact with the lower portion of the partition; and
a second cap layer provided on the second upper electrode, wherein
the partition surrounds the second organic layer, the second upper electrode and the second cap layer,
the second organic layer has a third end portion, and a fourth end portion located on a side opposite to the third end portion,
a thickness of the second cap layer immediately above the fourth end portion is greater than a thickness of the second cap layer immediately above the third end portion, and
a length which protrudes from the stem layer in the bottom layer facing the fourth end portion is greater than a length which protrudes from the stem layer in the bottom layer facing the third end portion.

11. A manufacturing method of a display device, the method comprising:
preparing a processing substrate in which a first lower electrode, a second lower electrode, a third lower electrode, an inorganic insulating layer and a partition are formed above a substrate, the inorganic insulating layer covering a peripheral portion of each of the first, second and third lower electrodes, the partition including a lower portion located on the inorganic insulating layer and an upper portion which is located on the lower portion and protrudes from a side surface of the lower portion;
forming a first stacked film including a first organic layer including a first light emitting layer, a first upper electrode located on the first organic layer, and a first cap layer located on the first upper electrode, on the first lower electrode;
forming a first sealing layer using an inorganic insulating material on the first stacked film;
patterning the first stacked film and the first sealing layer;
forming a second stacked film including a second organic layer including a second light emitting layer different from the first light emitting layer, a second upper electrode located on the second organic layer, and a second cap layer located on the second upper electrode, on the second lower electrode;
forming a second sealing layer using an inorganic insulating material on the second stacked film; and
patterning the second stacked film and the second sealing layer, wherein
at least one first evaporation source for forming the first cap layer and a second evaporation source for forming the second upper electrode incline with respect to a normal of the processing substrate, and
evaporation directions for forming the first cap layer and the second upper electrode are same as each other.

12. The manufacturing method of claim 11, further comprising:
after patterning the second stacked film and the second sealing layer,
forming a third stacked film including a third organic layer including a third light emitting layer different from the first light emitting layer and the second light emitting layer, and a third upper electrode located on the third organic layer, on the third lower electrode;
forming a third sealing layer using an inorganic insulating material on the third stacked film; and
patterning the third stacked film and the third sealing layer, wherein
at least one third evaporation source for forming the second cap layer and a fourth evaporation source for forming the third upper electrode incline with respect to the normal of the processing substrate, and
evaporation directions for forming the second cap layer and the third upper electrode are same as each other.

13. The manufacturing method of claim 12, wherein
the evaporation directions for forming the second cap layer and the second upper electrode are same as each other.

14. The manufacturing method of claim 11, wherein
the patterning the first stacked film and the first sealing layer includes:
forming a resist patterned into a predetermined shape on the first sealing layer;
removing the first sealing layer and the first stacked film in order using the resist as a mask; and
removing the resist.

15. The manufacturing method of claim 14, wherein
an etching rate of the first cap layer at a time of removing the first sealing layer is less than an etching rate of the first sealing layer.
